(19) United States
(12) Patent Application Publication
(10) Pub. No.: US 2025/0379503 A1
(43) Pub. Date: Dec. 11, 2025

(54) DISTRIBUTED POWER SUPPLY

(71) Applicant: SKYWORKS SOLUTIONS, INC., Irvine, CA (US)

(72) Inventors: Chung Liang Lee, Irvine, CA (US); Xinliang Wang, Irvine, CA (US); Bogdan Stefan Fulga, Ottawa (CA)

(21) Appl. No.: 19/207,866

(22) Filed: May 14, 2025

Related U.S. Application Data
(60) Provisional application No. 63/648,035, filed on May 15, 2024.

(51) Int. Cl. H02M 1/00; H02M 3/155

(52) U.S. Cl. CPC H02M 1/0083; H02M 3/155

(57) ABSTRACT

A device may include a first front-end module (FEM) configured to receive a supply voltage, the first FEM comprising a power management integrated circuit (PMIC) coupled to a voltage line. A device may include a second FEM coupled to the PMIC via the voltage line, the PMIC configured to distribute voltage to the second FEM via the voltage line.

### CROSS-REFERENCE TO RELATED APPLICATION(S)

This application claims priority to U.S. Provisional Application No. 63/648,035 filed May 15, 2024, entitled DISTRIBUTED POWER SUPPLY, the disclosure of each of which is hereby expressly incorporated by reference herein in its respective entirety.

### BACKGROUND

### Field

The present disclosure generally relates to power management of power amplifiers and front-end circuitry used in electronic devices.

### Description of the Related Art

Power management of power amplifiers and other front-end circuitry for various frequency bands may be needed for simultaneous communications over more than one band at a time.

### SUMMARY

In some implementations, the present disclosure relates to a power management system including a first front-end module (FEM) configured to receive a supply voltage, the first FEM including a power management integrated circuit (PMIC) coupled to a voltage line; and a second FEM coupled to the PMIC via the voltage line, the PMIC configured to distribute voltage to the second FEM via the voltage line.

In some aspects, the system further includes a third FEM coupled to the PMIC via the voltage line, wherein the PMIC is further configured to distribute voltage to the third FEM via the voltage line. The PMIC may be configured to distribute a common voltage to the second FEM and to the third FEM.

The PMIC may be configured to distribute different voltages to the second FEM and to the third FEM. In some aspects, the PMIC is configured to distribute voltage to the second FEM without distributing voltage to the third FEM.

In some aspects, the first FEM and the second FEM have identical architectures apart from the PMIC. The first FEM may include a first amplifier and a second amplifier.

The PMIC, the first amplifier, and the second amplifier may be disposed internally within a first semiconductor die.

Some implementations of the present disclosure relate to a power management system including a first front-end module (FEM) configured to receive a supply voltage, the first FEM including a power management integrated circuit (PMIC) coupled to a voltage line; a second FEM coupled to the PMIC via the voltage line, the PMIC configured to distribute voltage to the second FEM via the voltage line; and a third FEM coupled to the PMIC via the voltage line, the PMIC being further configured to distribute voltage to the third FEM via the voltage line.

In some aspects, the PMIC is configured to distribute a common voltage to the second FEM and to the third FEM. The PMIC may be configured to distribute different voltages to the second FEM and to the third FEM.

The PMIC may be configured to distribute voltage to the second FEM without distributing voltage to the third FEM. In some aspects, first FEM includes a first amplifier and a second amplifier.

In some aspects, the PMIC, the first amplifier, and the second amplifier are disposed internally within a first semiconductor die.

In accordance with some implementations, the present disclosure relates to a power management system including a first front-end module (FEM) configured to receive a supply voltage, the first FEM including a first amplifier, a second amplifier, and a power management integrated circuit (PMIC), the PMIC being coupled to a voltage line; and a second FEM coupled to the PMIC via the voltage line, the PMIC configured to distribute voltage to the second FEM via the voltage line.

In some aspects, the system further includes a third FEM coupled to the PMIC via the voltage line, wherein the PMIC is further configured to distribute voltage to the third FEM via the voltage line. The PMIC may be configured to distribute a common voltage to the second FEM and to the third FEM.

The PMIC may be configured to distribute different voltages to the second FEM and to the third FEM. In some aspects, the PMIC is configured to distribute voltage to the second FEM without distributing voltage to the third FEM.

In some aspects, the first FEM and the second FEM have identical architectures apart from the PMIC.

For purposes of summarizing the disclosure, certain aspects, advantages, and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 illustrates an example distributed power supply system in accordance with one or more examples.

FIG. 2 illustrates a power management integrated circuit (PMIC) having one or more features as described herein implemented on a semiconductor die.

FIG. 3 illustrates a power management unit (PMU) having one or more features as described herein implemented on a packaged module.

FIG. 4 depicts an example wireless device having one or more advantageous features described herein.

### DESCRIPTION

The headings provided herein, if any, are for convenience only and do not necessarily affect the scope or meaning of the claimed invention.

Power management using regulators and/or power management units is widely used in wireless devices, such as smartphones and other mobile devices, to increase the power amplifier (PA) efficiency and linearity. Certain protocols and wireless standards use relatively high bandwidths and therefore, improvements to typical power management strategies would be advantageous. For example, LTE advanced uses higher modulation bandwidth (e.g., about 40 MHz) than previous standards (e.g., less than or equal to about 20 MHZ). In another example, HPUE support requires an increase in current over existing requirements for low, mid, and high-band communications. In addition, uplink carrier aggregation of two or more cellular bands results in the need for increased power to be delivered by the PA. A typical front-end module designed to handle these protocols (e.g., LTE Advanced) generally includes filters and switches that may not have been previously used or necessary. This increase in components can result in additional losses in the transmission path. Accordingly, there is a need to increase efficiency of power supply to accommodate these additional losses and increases in power requirements for updated communication standards. Another driving design principle is to reduce the overall area usage of modules and components in a device implementing such an RF communication system (e.g., a wireless device). Disclosed herein are various examples of circuits, devices and methods that can be configured to, among other things, address the foregoing challenges associated with power management systems.

Some power management systems utilize a power management integrated circuit (PMIC) and/or power management unit (PMU), which can include a set of DC-DC converters, such as a boost converter and/or buck/boost converter. In some implementations, a PMIC and/or PMU includes a controller block configured to open and close one or more switches corresponding to each DC-DC converter.

A PMIC and/or PMU can include one or more switches corresponding to DC-DC converters. In some examples, the switches of the one or more DC-DC converters may be implemented as diodes, field-effect transistors (FETs), bipolar-junction transistors (BJTs) or any other comparable switching device.

To increase efficiency of a radio-frequency (RF) system, it may be advantageous to distribute power supply among access points of the system. Some methods of distributing power supply involve utilizing a power supply tree centralized away from a main PMU. In such systems, power trees may be generated for each RF and/or mixed signal sub-system. However, such systems may lack flexibility of the voltage that the power stage is supplied with and/or may have a reduced ability to improve and/or maximize efficiency.

Some systems and/or methods described herein relate to an independent power supply architecture for providing improved efficiency of RF and/or other systems. In some examples, systems may involve a master-slave distribution of power to improve cost and/or thermal dissipation.

Some RF systems may utilize a DC-DC converter (e.g., 12V to 5V DC-DC converter) connected to one or more front-end modules (FEMs) of the same band. Such systems can require the one or more FEMs to operate at a maximum of 5V with either +/−5% tolerance and/or +/−10% tolerance. Moreover, a low-dropout (LDO) regulator may be required to rectify overshoot and/or interference from the DC-DC converter.

Examples described herein can advantageously distribute power among one or more FEMs without requiring the FEMs to operate at 5V. In this way, the FEMs can operate at relatively higher efficiency. In some examples, one or more DC-DC converters may be integrated into an FEM to reduce a form factor.

Some examples described herein provide a master-slave power supply topology configured to provide improved voltage supply to one or more FEMs to achieve improved efficiency. Master-slave power supply systems described herein can be configured to minimize ripple to the FEMs, which can lead to improved RF performance and/or reduced dynamic error vector magnitude (DEVM) degradation.

In some examples, a master-slave power supply may be configured to efficiently convert an operation voltage (e.g., 12V) to a specific and/or desired voltage supply to a master FEM and/or one or more slave FEMs.

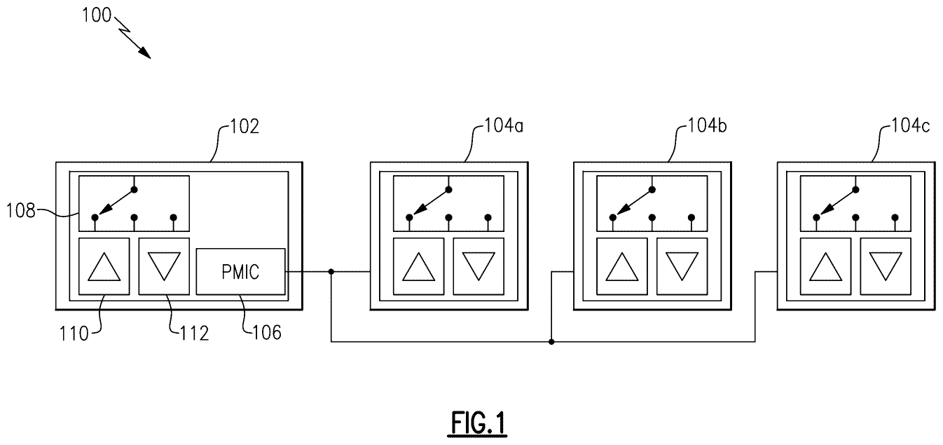

FIG. 1 illustrates an example distributed power supply system 100 in accordance with one or more examples. The system 100 may comprise a master FEM 102 and/or one or more slave FEMs 104, which can include a first slave FEM 104a, a second slave FEM 104b, and/or a third slave FEM 104c. While the system 100 is shown comprising three slave FEMs 104, example systems can include more or fewer slave FEMs 104.

The master FEM 102 and/or slave FEMs 104 may comprise one or more switches 108 and/or amplifiers (e.g., low-noise amplifiers (LNAs)), which can include a first amplifier 110 and/or a second amplifier 112. The master FEM 102 may have a common architecture relative to the one or more slave FEMs 104. However, the master FEM 102 may comprise one or more additional components, including a PMIC 106 configured to provide a power supply to the one or more slave FEMs 104. Apart from the PMIC 106, the master FEM 102 may have an identical and/or common architecture relative to the one or more slave FEMs 104. The PMIC 106 may be configured to supply a common voltage to each of the slave FEMs 104. In some examples, the PMIC 106 may be coupled to the first slave FEM 104a, the second slave FEM 104b, and/or the third FEM 104c via one or more voltage lines.

The PMIC 106 may comprise an integrated architecture and/or may comprise various functional circuit blocks onboard the PMIC 106. The system 100 may comprise multiple RF streams and/or may include any number of RF streams.

The master FEM 102 and/or slave FEMs 104 may each comprise an access point and/or may comprise several supply voltage rails, which may each support up to 14V. Only the master FEM 102 may comprise the PMIC 106 and/or the slave FEMs 104 may not comprise a PMIC and/or PMU. Instead, the master FEM 102 may be configured to receive a relatively high voltage supply (e.g., up to 14V) and/or to distribute the voltage supply at the master FEM 102 and/or the one or more slave FEMs 104. In this way, voltage supply to the slave FEMs 104 may be effectively and/or efficiently controlled. Moreover, output power of the master FEM 102 may be controlled by changing the voltage supply provided to the master FEM 102. The system 100 may advantageously be configured to maintain power added efficiency (PAE) across a range of output power values. Use of a PMIC 106 internally within the master FEM 102 may advantageously allow for control of voltage supply within the system 100 without use of an external power supply. Moreover, the system 100 may require only one PMIC 106 and/or only one FEM comprising a PMIC 106. The PMIC 106 may be disposed internally within a semiconductor die with the other components of the master FEM 102.

In some examples, the PMIC 106 may be configured to supply a common power and/or voltage supply to each of the slave FEMs 104. Alternatively, the PMIC 106 may be configured to supply different voltage and/or power to different slave FEMs 104. For example, the PMIC 106 may be configured to distribute a first voltage and/or power to the first slave FEM 104a and/or a second voltage and/or power to the second slave FEM 104b. The PMIC 106 may be configured to supply power to the slave FEMs 104 concurrently (e.g., simultaneously) and/or separately. For example, the PMIC 106 may be configured to supply power to the first slave FEM 104a without supplying power to the second slave FEM 104b and/or alternate power supply to the second FEM 104b without supplying power to the first FEM 104a.

The PMIC 106 may be configured to supply as little power as possible to achieve a quality signal. In some examples, the power supply may be increased and/or decreased autonomously.

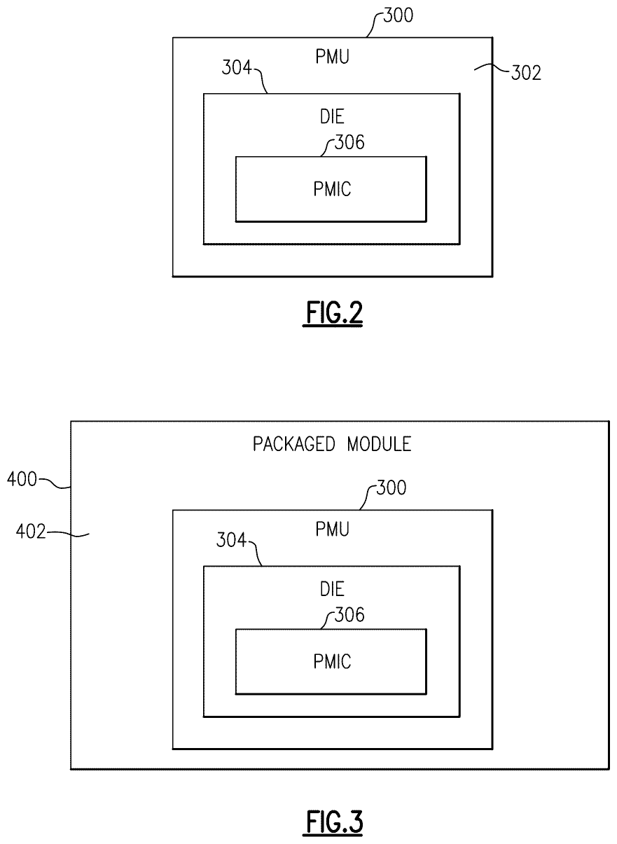

FIG. 2 shows that in some embodiments, some or all of a power management integrated circuit (PMIC) 306 having one or more features as described herein can be implemented on a semiconductor die 304. Additionally, a PMU 300, as described herein, may implement a die 304 with a PMIC 306. Such a PMU 300 can include a substrate 302 configured to implement some or all of one or more components such as inductors, capacitors, resistors, filters, pins, ports, and/or other interfacing parts.

In some embodiments, some or all of the capacitances and inductances utilized by PMIC 306 within PMU 300 can be implemented on the foregoing substrate 302. For example, a capacitance can be implemented as a MIM (metal-insulator-metal) capacitor, a MIS (metal-insulator-semiconductor) capacitor, a modified form of transistor, etc. An inductance can be implemented as a metal trace, a portion of a conductor, or some combination thereof.

Additionally, die 304 may also have a semiconductor substrate. In the context of the example switches described herein, the semiconductor substrate 302 can be, for example, a silicon substrate, a silicon-germanium substrate, or a silicon-on-insulator (SOI) substrate, if the switches are implemented as field-effect transistors (FETs). In another example, where bipolar-junction transistors (BJTs) are utilized in the PMIC 306, the semiconductor substrate can be, for example, a silicon substrate or a gallium arsenide substrate.

FIG. 3 shows that in some embodiments, some or all of a PMU 300 having one or more features as described herein can be implemented on a packaged module 400. Such a module can include a packaging substrate 402 configured to receive a plurality of components such as one or more die, one or more modules and one or more passive components.

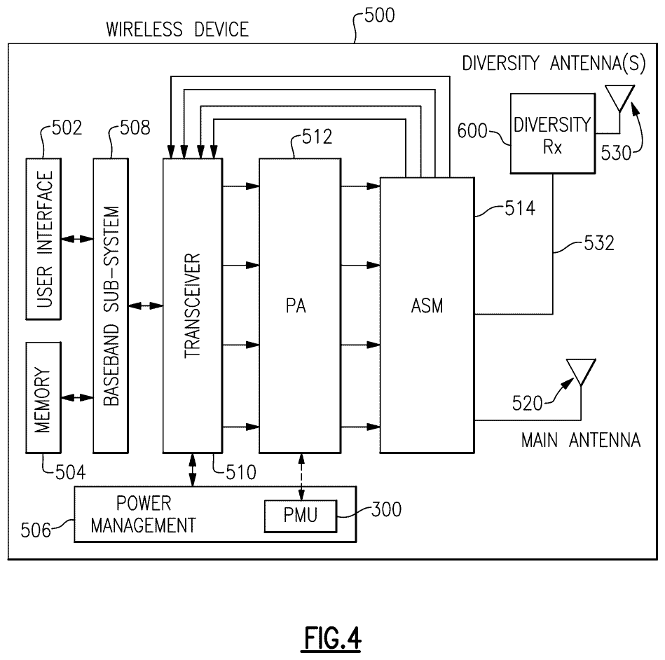

FIG. 4 depicts an example wireless device 500 having one or more advantageous features described herein. In some embodiments, a power management unit having one or more features as described herein can be implemented in each of one or more places in such a wireless device. For example, in some embodiments, such advantageous features can be implemented in a module such as a power management module 506 having one or more power management units (PMUs).

In the example of FIG. 4, power amplifiers (PAs) in a PA module 512 can receive their respective RF signals from a transceiver 510 that can be configured and operated to generate RF signals to be amplified and transmitted, and to process received signals. The transceiver 510 is shown to interact with a baseband sub-system 508 that is configured to provide conversion between data and/or voice signals suitable for a user and RF signals suitable for the transceiver 510. The transceiver 510 is also shown to be connected to a power management module 506 that is configured to manage power for the operation of the wireless device 500. Such power management can also control operations of the baseband sub-system 508 and/or other components of the wireless device 500. In some embodiments, a PMU 300 is implemented within power management module 506, while in some implementations, a PMU 300 is implemented as a distinct module within wireless device 500. In some implementations, power management module 506 and/or PMU 300 are directly connected to the PA module 512.

The baseband sub-system 508 is shown to be connected to a user interface 502 to facilitate various input and output of voice and/or data provided to and received from the user. The baseband sub-system 508 can also be connected to a memory 504 that is configured to store data and/or instructions to facilitate the operation of the wireless device, and/or to provide storage of information for the user.

In the example of FIG. 4, the DRx module 600 can be implemented between one or more diversity antennas (e.g., diversity antenna 530) and the antenna switch module (ASM) 514. Such a configuration can allow an RF signal received through the diversity antenna 530 to be processed (in some embodiments, including amplification by an LNA) with little or no loss of and/or little or no addition of noise to the RF signal from the diversity antenna 530. Such processed signal from the DRx module 600 can then be routed to the ASM through one or more signal paths.

In the example of FIG. 4, a main antenna 520 can be configured to, for example, facilitate transmission of RF signals from the PA module 512. In some embodiments, receive operations can also be achieved through the main antenna.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

It is noted that while some examples are described herein in the context of carrier aggregation of two bands, one or more features of the present disclosure can also be implemented in configurations involving carrier aggregation of different numbers of bands.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions, and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A power management system comprising:
a first front-end module (FEM) configured to receive a supply voltage, the first FEM comprising a power management integrated circuit (PMIC) coupled to a voltage line; and
a second FEM coupled to the PMIC via the voltage line, the PMIC configured to distribute voltage to the second FEM via the voltage line.

2. The system of claim 1 further comprising a third FEM coupled to the PMIC via the voltage line, wherein the PMIC is further configured to distribute voltage to the third FEM via the voltage line.

3. The system of claim 2 wherein the PMIC is configured to distribute a common voltage to the second FEM and to the third FEM.

4. The system of claim 2 wherein the PMIC is configured to distribute different voltages to the second FEM and to the third FEM.

5. The system of claim 2 wherein the PMIC is configured to distribute voltage to the second FEM without distributing voltage to the third FEM.

6. The system of claim 1 wherein the first FEM and the second FEM have identical architectures apart from the PMIC.

7. The system of claim 1 wherein the first FEM comprises a first amplifier and a second amplifier.

8. The system of claim 7 wherein the PMIC, the first amplifier, and the second amplifier are disposed internally within a first semiconductor die.

9. A power management system comprising:
a first front-end module (FEM) configured to receive a supply voltage, the first FEM comprising a power management integrated circuit (PMIC) coupled to a voltage line;
a second FEM coupled to the PMIC via the voltage line, the PMIC configured to distribute voltage to the second FEM via the voltage line; and
a third FEM coupled to the PMIC via the voltage line, the PMIC being further configured to distribute voltage to the third FEM via the voltage line.

10. The system of claim 9 wherein the PMIC is configured to distribute a common voltage to the second FEM and to the third FEM.

11. The system of claim 9 wherein the PMIC is configured to distribute different voltages to the second FEM and to the third FEM.

12. The system of claim 9 wherein the PMIC is configured to distribute voltage to the second FEM without distributing voltage to the third FEM.

13. The system of claim 9 wherein the first FEM comprises a first amplifier and a second amplifier.

14. The system of claim 13 wherein the PMIC, the first amplifier, and the second amplifier are disposed internally within a first semiconductor die.

15. A power management system comprising:
a first front-end module (FEM) configured to receive a supply voltage, the first FEM comprising a first amplifier, a second amplifier, and a power management integrated circuit (PMIC), the PMIC being coupled to a voltage line; and
a second FEM coupled to the PMIC via the voltage line, the PMIC configured to distribute voltage to the second FEM via the voltage line.

16. The system of claim 15 further comprising a third FEM coupled to the PMIC via the voltage line, wherein the PMIC is further configured to distribute voltage to the third FEM via the voltage line.

17. The system of claim 16 wherein the PMIC is configured to distribute a common voltage to the second FEM and to the third FEM.

18. The system of claim 16 wherein the PMIC is configured to distribute different voltages to the second FEM and to the third FEM.

19. The system of claim 16 wherein the PMIC is configured to distribute voltage to the second FEM without distributing voltage to the third FEM.

20. The system of claim 15 wherein the first FEM and the second FEM have identical architectures apart from the PMIC.
